(19) United States
(12) Patent Application Publication
(10) Pub. No.: US 2006/0231848 A1
(43) Pub. Date: Oct. 19, 2006

(54) Light emitting diode package for enhancing light extraction

(76) Inventor: Chien-Kun Fu, Hukou Township (TW)

Correspondence Address: RABIN & BERDO, P.C., Suite 500, 1101 14 Street, N.W., Washington, DC, 20005, US

(21) Appl. No.: 11/105,507

(22) Filed: Apr. 14, 2005

(51) Int. Cl. H01L 29/18; H01L 33/00

(52) U.S. Cl. 257/88

(57) ABSTRACT

A light emitting diode package for enhancing light extraction includes a plurality of LED dies. A holder having a die pad on which the LED dies are seated and a plurality of pins is electrically connected to the plurality of LED dies respectively. A transparent molding covers the plurality of LED dies and the die pads to protect the plurality of LED dies, through which the pins are extended.

### BACKGROUND OF THE INVENTION

1. Field of Invention

The present invention relates to a package structure and particularly to a package structure of at least one light-emitting diode (LED).

2. Related Art

A light-emitting diode (LED) emits a light based on its semi-conductive characteristics in contrast to the heat-induced light principle of a fluorescent lamp, and is thus called a cold light. The LED is equipped with a number of advantages such as high endurance, a long lifetime, compactness, low power consumption and so forth. Further, no pernicious material such as mercury material is contained in the LED and thus the LED is suitable to be a light-emitting device of assortments of appliances, display panels and communication products. It is to be noted that an LED die may be manufactured with a monochromatic light generated with control of the used materials and manufacturing processes.

Since the LED may save power up to a considerable extent, it may be expected that future lighting equipment, such as a bulb, may be largely replaced by the LED. Therefore, the LED is expected to be a widely used light source for our daily life in the current lighting market. Among the mentioned potential LED-based lighting equipment, lamps are naturally dispensable, such as a projection light, a vehicle lamp, a household lamp, a streetlamp and the like. However, a single LED die may have a limited luminance and in view of this problem at least one LED die is generally packaged in a single light-emitting body. In case of an application of larger lighting device, these light-emitting bodies are combined as a particular light-emitting module, depending on the real application and requirements.

For a prior package of the LED, there are two metal pins 100 and an LED die 110, as shown in FIG. 1. The LED 110 has two electrodes connected respectively to the two metal pins 100, wherein one of the two metal pins 100 may comprise a small cup to load the LED die 110 thereon. Then, a molding is directly packaged onto the cup and the LED die 110, while one end of each of the metal pins 100 is exposed. However, this arrangement may provide a package for only an LED die 110, i.e., a plurality of LED dies may not be packaged through such a technology. To promote the luminance of the LED die to be used as a larger light-emitting module or a lamp, a plurality of LED dies are required to be packaged as a light-emitting body and additional manufacturing steps are also unavoidable.

In achieving the light-emitting body or module above, the steps of packaging the LED dies must be put into process with an accurate alignment, such as die bonding, wire bonding and molding. Only in this manner may the LED dies be accurately bonded on the cup and the wires are bonded to the electrodes and metal pins of the LED dies.

### SUMMARY OF THE INVENTION

In view of the drawbacks encountered with the prior arts, it is an object of the present invention to provide a light-emitting diode (LED) package for enhancing light extraction, in which a plurality of LED dies are amounted on a holder and then a molding is applied thereon. As such, brightness of the LED dies may increase as compared to a single LED die.

To accomplish the object above, the LED package for enhancing light extraction in accordance with the present invention comprises a plurality of LED dies, a frame having a die pad on which a plurality of LED dies is seated, a plurality of pins is electrically connected to the plurality of LED dies, a transparent molding covers the plurality of LED dies and the dies pad to protect the plurality of LED dies, through which a plurality of pins is extended, wherein the light emitted from the plurality of LED dies may penetrate the transparent molding to the ambient environment outside the molding. The extended pins are arranged to connect electrically to an external power.

In accordance with the LED package for enhancing light extraction of the present invention, the holder may be a currently used lead frame comprising the die pad and the plurality of pins, separated with a predetermined distance therewith. The pin comprises an internal pin portion which is oriented to the die pad and which is connected electrically to the plurality of LED dies, and an external pin portion extending out through the transparent molding.

The features and implementations of the present invention will be described in detail through the preferred embodiments, in connection with the attached drawings.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention. In the drawings:

FIG. 1 is a sectional view of a prior light-emitting diode (LED) package; and

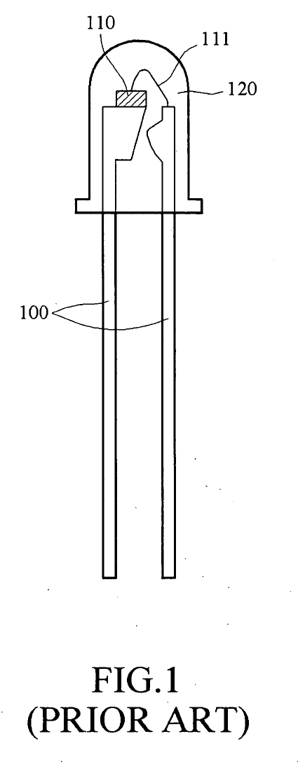

FIG. 2 is a side elevated view of an LED package for enhancing light extraction in accordance with the present invention.

### DETAILED DESCRIPTION OF THE INVENTION

The present invention discloses a light-emitting diode (LED) package for enhancing light extraction, in which a plurality of LED dies are integrally formed on a holder to enhance lightness of the LED package. Concurrently, the manufacturing- process and cost for the LED are simplified and reduced respectively. Further, the holder used may be a lead frame of a chip of the LED package, and the plurality of LED dies may be bonded directly to the lead frames.

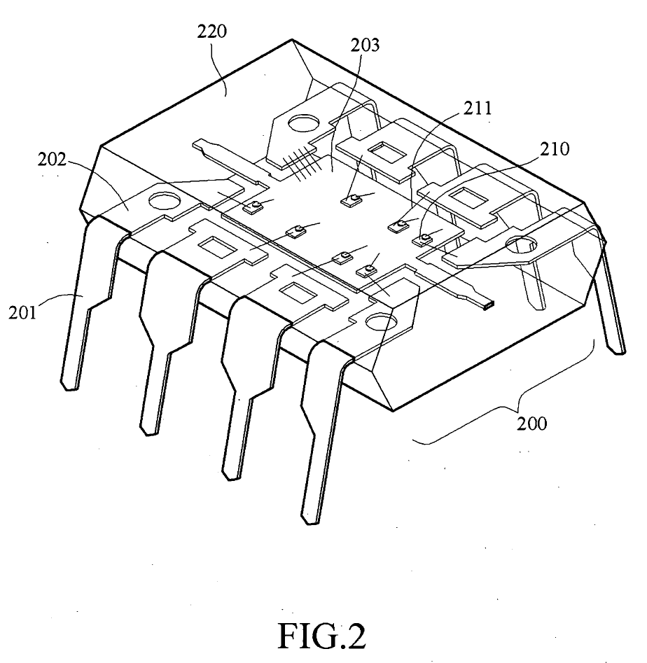

Referring to FIG. 2, a side elevated view of an embodiment of the LED package for enhancing light extraction according to the present invention is illustrated therein. The LED package comprises lead frames 200, a plurality of LED dies 210 and a transparent molding 220. The lead frames 200 comprise a die pad 203 and a plurality of pins. The plurality of LED dies is bonded onto the die pad 203 through glue. The plurality of pins is separated with the die pad 203, with a predetermined distance. Each of the pins includes an internal pin portion 202 and an external pin portion 201. For each of the pins, the internal pin portion 202 is oriented to the die pad 203 and is connected electrically to the plurality of LED dies 210 through wire bonding. The transparent molding 220 covers the plurality of LED dies 210 and the die pad 203 to protect the plurality of LED dies 210. Since the molding 220 on the plurality of LED dies 210 is transparent in nature, a light generated by the plurality of LED dies 210 may be emitted to the ambient outside the molding 220. The external pin portion 201 extends out through the transparent molding 220 and used to connect electrically to an external power source or an external circuit. The scheme applying the currently existing lead frames 200 as the holder may not only reduce the cost of the LED package but also the external pin portion 201 of the pin may be drawn to a desired location. In addition, a plurality of LED dies is preferably connected in parallel.

In other embodiments, the LED package may also be provided with a plurality of condensing lenses disposed on an outer face of the molding and aligned with the light emitted from the plurality of LED dies so that the emitted light may be effectively condensed. Furthermore, the die pad of the holder or the lead frames may be coated with a reflective layer at a side bonding with the plurality of LED dies so that the light extraction may be further increased. In addition, a glue layer having fluorescent powders therein may be formed on each of the LED dies and this glue layer may be manufactured by blending the fluorescent powders into the glue layer.

In summary, the LED package for enhancing light extraction according to the present invention may be fabricated by using the now existing manufacturing processes and apparatus and the cost of the LED package may be reduced.

While embodiments and applications of this invention have been shown and described, it would be apparent to those skilled in the art having the benefit of this disclosure that more modifications than mentioned above are possible without departing from the inventive concepts herein. The invention, therefore, can only be interpreted in the spirit of the appended claims and their equivalents.

1. A light-emitting diode (LED) package for enhancing light extraction, comprising:
a plurality of LED dies;
a holder, comprising a die pad on which the LED dies is mounted and a plurality of pins connected electrically to the plurality of LED dies respectively; and
a transparent molding, covering the die pad and the LED dies to protect the LED dies, and the pins are extended outsides through the transparent molding to connect with an external power/an external circuit.

2. The LED package of claim 1, wherein the holder which is a lead frame and which has the
die pad and the pins separated with a predetermined distance therewith, and the pin which comprises an internal pin portion oriented to the die pad and connected electrically to the LED dies, and which comprises an external pin portion extending out through the transparent molding.

3. The LED package of claim 2, wherein a surface of the die pad mounting the LED dies is coated with a reflective layer.

4. The LED package of claim 1, wherein the LED dies are bonded onto the die pad through glue.

5. The LED package of claim 1, further comprising a plurality of condensing lens disposed over an outer surface of the transparent molding and aligned with the light emitted from the LED dies so that the emitted light from the LED dies may be effectively condensed.

6. The LED package of claim 1, wherein a surface of the die pad mounting the LED dies is coated with a reflective layer.

7. The LED package of claim 1, wherein a surface of the LED dies is covered with a glue layer having fluorescent powers.

8. The LED package of claim 7, wherein the glue layer having the fluorescent powers is formed by blending fluorescent powders into the glue layer.
